(19) United States
(12) Patent Application Publication
(10) Pub. No.: US 2022/0341732 A1
(43) Pub. Date: Oct. 27, 2022

(54) METHOD, DEVICE AND SYSTEM FOR MONITORING FLATNESS OF WAFER TABLE, AND STORAGE MEDIUM

(71) Applicant: CHANGXIN MEMORY TECHNOLOGIES, INC., Hefei City (CN)

(72) Inventor: MENG-HSUAN TSAI, Hefei (CN)

(21) Appl. No.: 17/677,168

(22) Filed: Feb. 22, 2022

Related U.S. Application Data
(63) Continuation of application No. PCT/CN2021/112884, filed on Aug. 17, 2021.

(30) Foreign Application Priority Data
Apr. 23, 2021 (CN) 202110443221.6

(51) Int. Cl. G01B 11/30; H01L 21/66

(52) U.S. Cl. CPC G01B 11/306; H01L 22/12

(57) ABSTRACT

A method for monitoring flatness of a wafer table includes: acquiring a yield and original focus data of a wafer in real time; obtaining an edge flatness curve of a wafer table based on the original focus data; obtaining a yield curve of the wafer based on the yield of the wafer; obtaining a trend diagram of the edge flatness and the yield over time based on the edge flatness curve and the yield curve; and determining, based on the trend diagram, an edge flatness value of the wafer table when the wafer table is replaced.

### CROSS-REFERENCE TO RELATED APPLICATIONS

The application is a continuation of International Application No. PCT/CN2021/112884, filed on Aug. 17, 2021, which claims priority to Chinese Patent Application No. 202110443221.6, filed on Apr. 23, 2021. The disclosures of International Application No. PCT/CN2021/112884 and Chinese Patent Application No. 202110443221.6 are hereby incorporated by reference in their entireties.

### TECHNICAL FIELD

The disclosure relates to the technical field of semiconductors, and in particular relates to a method, device and system for monitoring flatness of a wafer table, and a storage medium.

### BACKGROUND

In the production process of a wafer, the flatness of a wafer table directly affects an exposure result, resulting in a chuck spot of the wafer table and reducing the yield of the wafer. At present, when the wafer is processed, it is necessary to install the wafer on the wafer table. In the process of loading and unloading, due to gravity and other factors, there is more contact between the wafer and an edge of the wafer table, resulting in relatively rapid abrasion of the edge of the wafer table, which affects a production wafer edge process window and reduces the yield of the wafer part located at the edge of the wafer table.

There are two methods for monitoring flatness of a wafer table commonly used in a traditional art. The first method is to use a standard wafer of a manufacturer to implement in-line measurement of the flatness of the wafer table. However, the standard wafer has short service life and is expensive. The second method is to stop and use control chip measurement. However, the method cannot implement in-line measurement, but needs to stop a tool, which increases the tool up time, thus affecting the wafer processing efficiency.

### SUMMARY

According to an aspect, embodiments of the disclosure provide a method for monitoring flatness of a wafer table, which may include the following operations. A yield of a wafer and original focus data of the wafer detected by a focus monitor are acquired in real time. An edge flatness curve of a wafer table is obtained based on the original focus data, the edge flatness curve representing a change of edge flatness of the wafer table over time. A yield curve of the wafer is obtained based on the yield of the wafer, the yield curve representing a change of the yield of the wafer over time. A trend diagram of the edge flatness and the yield over time is obtained based on the edge flatness curve and the yield curve. An edge flatness value of the wafer table when the wafer table is replaced is determined based on the trend diagram.

According to another aspect, embodiments of the disclosure provide a device for monitoring flatness of a wafer table, which may include a memory storing processor-executable instructions and a processor. The processor is configured to execute the stored processor-executable instructions to perform operations of: acquiring, in real time, a yield of a wafer and original focus data of the wafer detected by a focus monitor; obtaining an edge flatness curve of a wafer table based on the original focus data, the edge flatness curve representing a change of edge flatness of the wafer table over time; obtaining a yield curve of the wafer based on the yield of the wafer, the yield curve representing a change of the yield of the wafer over time; obtaining a trend diagram of the edge flatness and the yield over time based on the edge flatness curve and the yield curve; and determining, based on the trend diagram, an edge flatness value of the wafer table when the wafer table is replaced.

According to yet another aspect, embodiments of the disclosure provide a system for monitoring flatness of a wafer table, which may include a yield test device, a focus monitor and a controller. The yield test device is configured to detect a yield of a wafer in real time. The focus monitor is configured to detect original focus data of the wafer in real time. The controller includes a memory and a processor. The memory stores computer-executable instructions, and the processor executes the computer-executable instructions to perform operations of: acquiring, in real time, the yield of the wafer and the original focus data of the wafer detected by the focus monitor; obtaining an edge flatness curve of a wafer table based on the original focus data, the edge flatness curve representing a change of edge flatness of the wafer table over time; obtaining a yield curve of the wafer based on the yield of the wafer, the yield curve representing a change of the yield of the wafer over time; obtaining a trend diagram of the edge flatness and the yield over time based on the edge flatness curve and the yield curve; and determining, based on the trend diagram, an edge flatness value of the wafer table when the wafer table is replaced.

### BRIEF DESCRIPTION OF THE DRAWINGS

In order to describe the technical solutions in the embodiments of the disclosure or a conventional art more clearly, the drawings required to be used in descriptions about the embodiments or the conventional art will be simply introduced below. It is apparent that the drawings described below are only some embodiments of the disclosure. Other drawings may further be obtained by those of ordinary skilled in the art according to these drawings without creative work.

FIG. 1 is a flowchart of a method for monitoring flatness of a wafer table provided in an embodiment of the disclosure.

FIG. 2 is a flowchart of a method for monitoring flatness of a wafer table provided in another embodiment of the disclosure.

FIG. 3 is a schematic diagram of a relationship curve between the focus and the radius at each position on a wafer provided in an embodiment of the disclosure.

FIG. 4 is a schematic diagram of an edge flatness curve of a wafer table provided in an embodiment of the disclosure.

FIG. 5 is a trend diagram of the edge flatness of a wafer table and the yield of a wafer over time provided in an embodiment of the disclosure.

FIG. 6 is a structural block diagram of a device for monitoring flatness of a wafer table provided in an embodiment of the disclosure.

### DESCRIPTION OF THE REFERENCE SIGNS IN THE DRAWINGS

60 Device for monitoring flatness of a wafer table; 61 Acquiring module; 62 Processing module; and 63 Flatness determining module.

### DETAILED DESCRIPTION

In order to make the disclosure convenient to understand, the disclosure will be described more comprehensively below with reference to the related drawings. The drawings show preferred embodiments of the disclosure. However, the disclosure may be implemented in various forms and is not limited to the embodiments described herein. Instead, these embodiments are provided to make the contents disclosed in the disclosure understood more thoroughly and comprehensively.

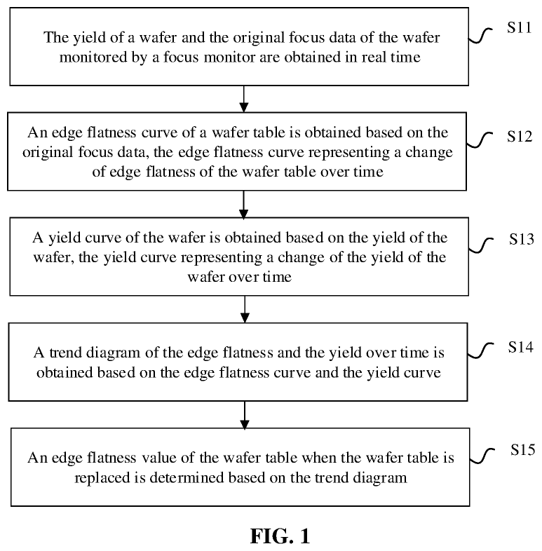

FIG. 1 is a flowchart of a method for monitoring flatness of a wafer table in an embodiment. Referring to FIG. 1, a method for monitoring flatness of a wafer table may include the following operations.

At S11, a yield of a wafer and original focus data of the wafer detected by a focus monitor are acquired in real time.

Specifically, the focus at each position on the wafer is monitored in real time by the focus monitor. For example, the focus monitor may be a Phase Shift Focus Monitor (PSFM), etc. At each time, there is a focus value at each of different positions of the wafer. The focus monitor may monitor the focuses of all positions on the wafer at each time. The wafer is generally circular. Therefore, the original focus data may be classified according to positions having different distances from a center point of the wafer along the radius direction. The focus at each position of the wafer may also be called a focus at each of different radii (radius herein refers to a distance from a focus of the wafer). For example, the focus on the wafer at a position 100 mm away from the center point of the wafer is called the focus corresponding to the radius of 100 mm. The wafer used in the embodiment is not limited to a standard wafer, and may also be an ordinary wafer. The original focus data of the wafer detected by the focus monitor may be recorded in a process flow report of a lithography machine, and the original focus data of the wafer may be acquired in real time through the report.

With the increase of the service time of a wafer table, the edge abrasion of the wafer table will gradually increase, and the yield of the wafer will gradually decrease. A yield test device may be configured to detect the yield of the wafer in real time. The yield of the detected wafer at different times may be recorded in the process flow report of the lithography machine, and the yield of the wafer may be acquired in real time through the report.

At S12, an edge flatness curve of a wafer table is obtained based on the original focus data, the edge flatness curve representing a change of edge flatness of the wafer table over time.

Specifically, the inventor creatively finds that, with the increase of the service time of the wafer table, the edge abrasion of the wafer table will gradually increase, that is, the flatness of the edge of the wafer table will change, which will affect the wafer fixed on it, resulting in a fact that different wafers at different times have different focuses at a same position on them. Therefore, it is possible to obtain, based on the original focus data acquired in real time, the edge flatness curve of the wafer table representing a change of edge flatness of the wafer table over time.

At S13, a yield curve of the wafer is obtained based on the yield of the wafer, the yield curve representing a change of the yield of the wafer over time.

Specifically, the yield of the wafer at different times may be obtained through the process flow report of the lithography machine, so as to obtain the yield curve of the wafer representing a change of the yield of the wafer over time.

At S14, a trend diagram of the edge flatness and the yield over time is obtained based on the edge flatness curve and the yield curve.

Specifically, the edge flatness curve and the yield curve may be integrated into a trend diagram. The horizontal coordinates of the edge flatness curve and the yield curve represent time, the vertical coordinate of the edge flatness curve may represent the edge flatness, and the vertical coordinate of the yield curve may represent the yield, so as to represent the trend of the edge flatness and the yield over time in the same coordinate system. Of course, in other examples, the vertical coordinate of the coordinate system may also represent the time, the horizontal coordinate of the edge flatness curve may represent the edge flatness, and the horizontal coordinate of the yield curve may represent the yield.

At S15, an edge flatness value of the wafer table when the wafer table is replaced is determined based on the trend diagram.

Specifically, the trend diagram may include the edge flatness curve of the wafer table and the yield curve of the wafer. According to a condition that the edge flatness curve and the yield curve of the wafer meet a certain preset relationship, a certain edge flatness value on the edge flatness curve may be determined as the edge flatness value of the wafer table when the wafer table is replaced.

According to the method for monitoring flatness of a wafer table, the original focus data of the wafer is acquired in real time to obtain a change of edge flatness of the wafer table over time. The wafer used here is not limited to a standard wafer, and may also be an ordinary wafer, which may improve the applicability of the monitoring method and reduce the cost. Moreover, the focus monitor acquires the original focus data of the wafer in real time without shutdown, so as to implement the in-line monitoring of the flatness of the wafer table without affecting the wafer processing efficiency. Moreover, according to the above method for monitoring flatness of a wafer table, the yield of the wafer is further acquired in real time to obtain the yield curve of the wafer, and the trend diagram of the edge flatness of the wafer table and the yield of the wafer over time is obtained according to the edge flatness curve and the yield curve, so as to determine the edge flatness of the corresponding wafer table when the wafer table is replaced. In this way, it is helpful for the operator to know when to replace the wafer table, so as to prevent the wafer table from being worn more than a certain degree, which results in low wafer yield.

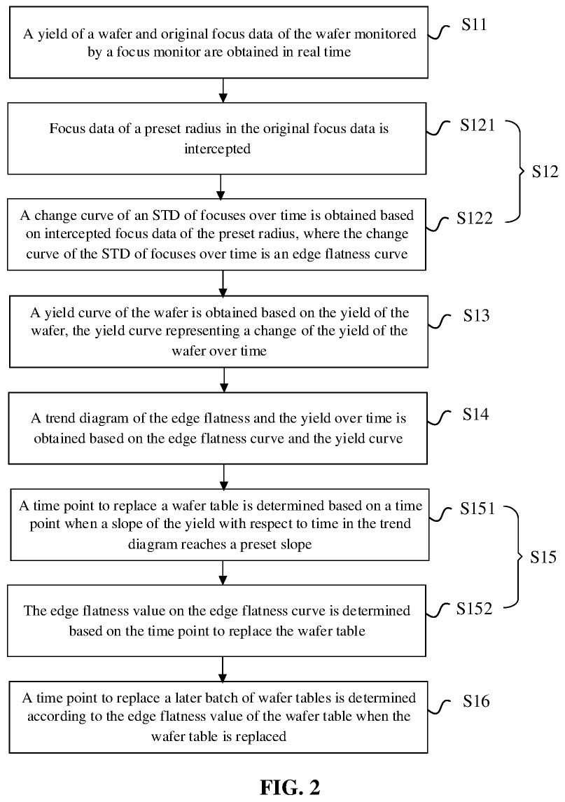

In some examples, the original focus data may include focus data corresponding to positions at different radii of the wafer. Referring to FIG. 2, in S12, the operation that the edge flatness curve of the wafer table is obtained based on the original focus data may include S121 to S122.

At S121, focus data of a preset radius in the original focus data is intercepted.

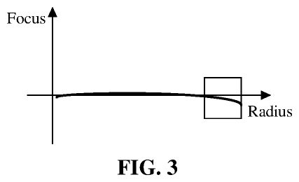

In some examples, referring to FIG. 3, a relationship curve between the focus and the radius at each position on the wafer may be obtained according to the original focus data, the horizontal coordinate of the relationship curve represents the radius, the vertical coordinate of the relationship curve represents the focus, and a part of the curve may be intercepted, Specifically, the curve of the preset radius may be intercepted according to the value of the horizontal coordinate (the curve in the box in FIG. 3 is the intercepted part).

In other examples, the preset radius and its corresponding focus data may be directly intercepted from the original focus data without forming the relationship curve between the focus and the radius at each position on the wafer.

In some examples, a range of the preset radius is positions 0-10 mm away from an edge of the wafer along a radius of the wafer, that is, the focus data corresponding to each position within the preset range of the edge of the wafer is intercepted. For example, when the diameter of the wafer is 300 mm, the preset radius range is positions where the radius of the wafer is 140-150 mm. Alternatively, the preset radius range may be positions 0-5 mm away from the edge of the wafer along the radius of the wafer. For example, when the diameter of the wafer is 300 mm, the preset radius range is positions where the radius of the wafer is 145-150 mm. Alternatively, the preset radius range may be positions 3-5 mm away from the edge of the wafer along the radius of the wafer. For example, when the diameter of the wafer is 300 mm, the preset radius range is positions where the radius of the wafer is 145-147 mm.

At S122, a change curve of a Standard Deviation (STD) of focuses over time is obtained based on intercepted focus data of the preset radius, where the change curve of the STD of focuses over time is the edge flatness curve.

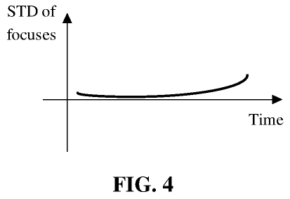

Specifically, referring to FIG. 4, the STD of focuses at all preset radii on the wafer at each time is calculated, and a coordinate system is established. The horizontal coordinate of the coordinate system represents time (dates), and the vertical coordinate of the coordinate system represents the STD of focuses at each preset radius. For different time points, the change curve of the STD of focuses over time, namely the edge flatness curve, is drawn. On the edge flatness curve, the size of the STD of focuses at each time may represent an overall flatness of the wafer table at that time.

In some examples, an average value of focuses at respective positions with the same radius on the wafer may be taken as the focus corresponding to the radius. Each radius corresponds to one focus. In S122, the STD of focuses corresponding to all preset radii on the wafer at each time is calculated.

In other examples, an average value of focuses at respective positions with the same radius on the wafer, among positions where the wafer in contact with the wafer table (namely, positions where the wafer may be worn), may be taken as the focus corresponding to the radius. Each radius corresponds to one focus. In S122, the STD of focuses corresponding to all preset radii on the wafer at each time is calculated.

In yet another embodiment, in S122, the STD of focuses at all positions of all preset radii on the wafer at each time may be calculated. Each radius corresponds to a plurality of focuses.

In still another embodiment, in S122, the STD of focuses at all positions where the wafer may be worn at all preset radii on the wafer at each time may be calculated. Each radius corresponds to a plurality of focuses.

In some examples, referring to FIG. 2, in S15, the operation that the edge flatness value of the wafer table when the wafer table is replaced is determined based on the trend diagram may include S151 to S152.

At S151, a time point to replace the wafer table is determined based on a time point when a slope of the yield with respect to time in the trend diagram reaches a preset slope.

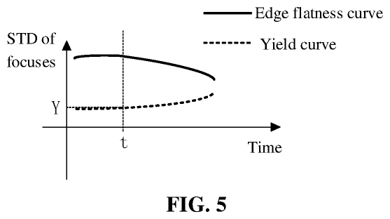

Specifically, referring to FIG. 5, in the trend diagram, the time point when the slope of the yield on the yield curve with respect to time reaches the preset slope is determined as the time point t to replace the table. The value of the preset slope may be comprehensively considered according to the cost, the benefit and the like, and may also be adjusted according to the process technology or characteristics of the wafer treating process. When the slope of the yield with respect to time reaches the preset slope, it means that the decline rate of the yield reaches the preset slope. At the time point t corresponding to the preset slope, the yield of the wafers is relatively low. The time point is determined as the time point t to replace the table, which may avoid too low yield of the wafer due to the subsequent reuse of the wafer table with serious abrasion. In other examples, the time point at which the yield in the trend diagram reaches the preset yield may also be determined as the time point to replace the wafer table.

In some examples, the preset slope ranges from 0.1 to 0.5. Alternatively, the preset slope is 0.1, 0.2, 0.3, 0.4 or 0.5.

At S152, the edge flatness value on the edge flatness curve is determined based on the time point to replace the wafer table.

Specifically, a vertical coordinate is found that corresponds to the horizontal coordinate on the edge flatness curve, the horizontal coordinate being the time point t to replace the wafer table, and the vertical coordinate is the determined edge flatness value Y of the wafer table when the wafer table is replaced. When the edge flatness of the wafer table reaches the value Y, the wafer table may be replaced.

In other examples, when the trend diagram of the edge flatness and the yield over time is obtained according to the yield curve and the edge flatness curve, the vertical coordinates of the yield and the STD of focuses may be reasonably set, so that the starting positions of the yield curve and the edge flatness curve are determined, and the edge flatness value corresponding to the intersection of the yield curve and the edge flatness curve is determined as the edge flatness value of the wafer table when the wafer table is replaced.

In some examples, referring to FIG. 2, a method for monitoring flatness of a wafer table may also include the following operations.

At S16, a time point to replace a later batch of wafer tables is determined according to the edge flatness value of the wafer table when the wafer table is replaced.

Specifically, for the first time, it is necessary to acquire the yield of the wafer in real time to obtain the yield curve. According to the yield curve and the flatness curve, the trend diagram of the edge flatness and the yield over time is obtained. Based on the trend diagram, the edge flatness value Y of the wafer table when the wafer table is replaced is determined. Subsequently, it is no longer necessary to acquire the yield of the wafer in real time, but only to acquire the original focus data of the wafer detected by the focus monitor in real time, obtain the edge flatness curve of the wafer table based on the original focus data, and find the time corresponding to the edge flatness value Y on the edge flatness curve, that is, the time point to replace the wafer table.

It should be understood that: although various steps in the flowcharts of FIG. 1 to FIG. 2 are sequentially displayed by following arrows, the steps are not sequentially executed necessarily in the order indicated by the arrows. Unless expressly stated in the description, there are no strict sequence restrictions on the execution of these steps, and these steps may be executed in other order. Moreover, at least part of steps in FIG. 1 to FIG. 2 may include a plurality of steps or a plurality of stages, these steps or stages are not executed necessarily at the same time, and may be executed at different times, and these steps or stages are not sequentially executed necessarily, and may be executed in turn or alternatively with other steps or at least part of steps or stages in other steps.

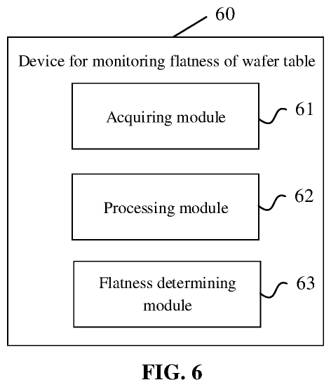

FIG. 6 is a device for monitoring flatness of a wafer table in an embodiment. Referring to FIG. 6, the device for monitoring flatness of a wafer table 60 may include an acquiring module, 61, a processing module 62 and a flatness determining module 63. The acquiring module 61 is configured to acquire, in real time, a yield of a wafer and original focus data of the wafer detected by a focus monitor. The processing module 62 is configured to obtain an edge flatness curve of a wafer table based on the original focus data, the edge flatness curve representing a change of flatness of the edge of the wafer table over time. The processing module 62 is further configured to obtain a yield curve of the wafer based on the yield of the wafer, the yield curve representing a change of the yield of the wafer over time. The processing module 62 is further configured to obtain a trend diagram of the edge flatness and the yield over time based on the edge flatness curve and the yield curve. The flatness determining module 63 is configured to determine, based on the trend diagram, an edge flatness value of the wafer table when the wafer table is replaced.

In some examples, the original focus data may include focus data corresponding to positions at different radii of the wafer. The processing module 62 may include an intercepting unit and a Standard Deviation (STD) processing unit. The intercepting unit is configured to intercept focus data of a preset radius in the original focus data. The STD processing unit is configured to obtain a change curve of an STD of focuses over time based on intercepted focus data of the preset radius, where the change curve of the STD of focuses over time is the edge flatness curve.

In some examples, a range of the preset radius is positions 0-10 mm away from an edge of the wafer along a radius of the wafer.

In some examples, the flatness determining module 63 may also include a replacement time determining unit and a flatness determining unit. The replacement time determining module is configured to determine a time point to replace the wafer table based on a time point when a slope of the yield with respect to time in the trend diagram reaches a preset slope. The flatness determining unit is configured to determine the edge flatness value on the edge flatness curve based on the time point to replace the wafer table.

In some examples, the flatness determining module 63 is further configured to determine a time point to replace a later batch of wafer tables according to the edge flatness value of the wafer table when the wafer table is replaced.

In some examples, the preset slope ranges from 0.1 to 0.5. Alternatively, the preset slope is 0.1, 0.2, 0.3, 0.4 or 0.5.

The specific definition of the device for monitoring flatness of a wafer table 60 may refer to the above definition of the method for monitoring flatness of a wafer table, which will not be elaborated here. Each module in the device for monitoring flatness of a wafer table 60 may be implemented in whole or in part by software, hardware and their combinations. The above modules may be embedded in or independent of a processor in a computer device in the form of hardware, and may also be stored in a memory in the computer device in the form of software, so as to facilitate the processor to call and execute the corresponding operations of the above modules.

The disclosure further provides a system for monitoring flatness of a wafer table. The system for monitoring flatness of a wafer table may include a yield test device, a focus monitor and a controller. The yield test device is configured to detect the yield of a wafer in real time. The focus monitor is configured to detect the original focus data of the wafer in real time. The controller may include a memory and a processor. The memory stores computer programs. When the processor executes the computer programs, the steps of the method for monitoring flatness of a wafer table in any of the above embodiments are performed.

In some examples, the focus monitor may include a phase shift focus monitor.

The disclosure further provides a computer readable storage medium having stored thereon computer programs, where the steps in the embodiments of the above methods are performed when the computer programs are executed by a processor.

Those of ordinary skill in the art will appreciate that implementing all or part of the processes in the methods described above may be accomplished by instructing associated hardware by a computer program, which may be stored in a non-volatile computer-readable storage medium, which, when executed, processes may be included as embodiments of the methods described above. Any reference to memory, storage, database, or other medium used in the various embodiments provided herein may include at least one of non-volatile and volatile memory. The non-volatile memory may include a Read-Only Memory (ROM), a magnetic tape, a floppy disk, a flash memory or an optical memory, etc. The volatile memory may include a Random Access Memory (RAM) or an external cache memory. As an illustration rather than limitation, the RAM may be in various forms, such as a Static Random Access Memory (SRAM) or a dynamic Random Access Memory (DRAM), etc.

Each technical feature of the above mentioned embodiments may be combined freely. For simplicity of description, not all possible combinations of each technical solution in the above mentioned embodiments are described. However, any combination of these technical features shall fall within the scope recorded in the specification without conflicting.

The above mentioned embodiments only express some implementations of the disclosure and are specifically described in detail and not thus understood as limits to the scope of the disclosure. It is to be pointed out that those of ordinary skill in the art may further make variations and modifications without departing from the concept of the disclosure and all of these fall within the scope of protection of the disclosure. Therefore, the scope of protection of the disclosure should be subject to protection scope of the appended claims.

1. A method for monitoring flatness of a wafer table, comprising:
acquiring, in real time, a yield of a wafer and original focus data of the wafer detected by a focus monitor;
obtaining an edge flatness curve of a wafer table based on the original focus data, the edge flatness curve representing a change of edge flatness of the wafer table over time;
obtaining a yield curve of the wafer based on the yield of the wafer, the yield curve representing a change of the yield of the wafer over time;
obtaining a trend diagram of the edge flatness and the yield over time based on the edge flatness curve and the yield curve; and
determining, based on the trend diagram, an edge flatness value of the wafer table when the wafer table is replaced.

2. The method for monitoring flatness of a wafer table of claim 1, wherein the original focus data comprises focus data corresponding to positions at different radii of the wafer; and
obtaining the edge flatness curve of the wafer table based on the original focus data comprises:
intercepting focus data of a preset radius in the original focus data; and
obtaining a change curve of a Standard Deviation (STD) of focuses over time based on intercepted focus data of the preset radius, wherein the change curve of the STD of focuses over time is the edge flatness curve.

3. The method for monitoring flatness of a wafer table of claim 2, wherein a range of the preset radius is positions 0-10 mm away from an edge of the wafer along a radius of the wafer.

4. The method for monitoring flatness of a wafer table of claim 1, wherein determining, based on the trend diagram, the edge flatness value of the wafer table when the wafer table is replaced comprises:
determining a time point to replace the wafer table based on a time point when a slope of the yield with respect to time in the trend diagram reaches a preset slope; and
determining the edge flatness value on the edge flatness curve based on the time point to replace the wafer table.

5. The method for monitoring flatness of a wafer table of claim 1, further comprising:
determining a time point to replace a later batch of wafer tables according to the edge flatness value of the wafer table when the wafer table is replaced.

6. The method for monitoring flatness of a wafer table of claim 4, wherein the preset slope ranges from 0.1 to 0.5.

7. A device for monitoring flatness of a wafer table, comprising:
a memory storing processor-executable instructions; and
a processor configured to execute the processor-executable instructions to perform operations of:
acquiring, in real time, a yield of a wafer and original focus data of the wafer detected by a focus monitor;
obtaining an edge flatness curve of a wafer table based on the original focus data, the edge flatness curve representing a change of edge flatness of the wafer table over time;
obtaining a yield curve of the wafer based on the yield of the wafer, the yield curve representing a change of the yield of the wafer over time;
obtaining a trend diagram of the edge flatness and the yield over time based on the edge flatness curve and the yield curve; and
determining, based on the trend diagram, an edge flatness value of the wafer table when the wafer table is replaced.

8. The device for monitoring flatness of a wafer table of claim 7, wherein the original focus data comprises focus data corresponding to positions at different radii of the wafer; and
obtaining the edge flatness curve of the wafer table based on the original focus data comprises:
intercepting focus data of a preset radius in the original focus data; and
obtaining a change curve of a Standard Deviation (STD) of focuses over time based on intercepted focus data of the preset radius, wherein the change curve of the STD of focuses over time is the edge flatness curve.

9. The device for monitoring flatness of a wafer table of claim 8, wherein a range of the preset radius is positions 0-10 mm away from an edge of the wafer along a radius of the wafer.

10. The device for monitoring flatness of a wafer table of claim 7, wherein determining, based on the trend diagram, the edge flatness value of the wafer table when the wafer table is replaced comprises:
determining a time point to replace the wafer table based on a time point when a slope of the yield with respect to time in the trend diagram reaches a preset slope; and
determining the edge flatness value on the edge flatness curve based on the time point to replace the wafer table.

11. The device for monitoring flatness of a wafer table of claim 7, wherein the processor is configured to execute the processor-executable instructions to further perform an operation of:
determining a time point to replace a later batch of wafer tables according to the edge flatness value of the wafer table when the wafer table is replaced.

12. The device for monitoring flatness of a wafer table of claim 10, wherein the preset slope ranges from 0.1 to 0.5.

13. A system for monitoring flatness of a wafer table, comprising a yield test device, a focus monitor and a controller,
wherein the yield test device is configured to detect a yield of a wafer in real time;
the focus monitor is configured to detect original focus data of the wafer in real time; and
the controller comprises a memory and a processor,
wherein the memory stores computer-executable instructions, and the processor executes the computer-executable instructions to perform operations of:
acquiring, in real time, the yield of the wafer and the original focus data of the wafer detected by the focus monitor;
obtaining an edge flatness curve of a wafer table based on the original focus data, the edge flatness curve representing a change of edge flatness of the wafer table over time;
obtaining a yield curve of the wafer based on the yield of the wafer, the yield curve representing a change of the yield of the wafer over time;
obtaining a trend diagram of the edge flatness and the yield over time based on the edge flatness curve and the yield curve; and
determining, based on the trend diagram, an edge flatness value of the wafer table when the wafer table is replaced.

14. The system for monitoring flatness of a wafer table of claim 13, wherein the focus monitor comprises a phase shift focus monitor.

15. A non-transitory storage medium having stored thereon computer-executable instructions, wherein the steps of the method of claim 1 are performed when the computer-executable instructions are executed by a processor.
